(19) United States
(12) Patent Application Publication
(10) Pub. No.: US 2021/0335804 A1
(43) Pub. Date: Oct. 28, 2021

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Teng-Hao YEH, Zhubei City (TW); Hang-Ting LUE, Hsinchu (TW); Chih-Wei HU, Miaoli County (TW)

(21) Appl. No.: 16/857,226

(22) Filed: Apr. 24, 2020

(51) Int. Cl. H01L 27/11582; H01L 27/11565; H01L 27/1157

(52) U.S. Cl. CPC H01L 27/11582; H01L 27/1157; H01L 27/11565

(57) ABSTRACT

A semiconductor structure and a method for manufacturing the same. The semiconductor structure includes a first staircase structure, a second staircase structure, a conductive pillar, and a contact pillar. The first staircase structure includes conductive stair layers. The conductive pillar passes through the second staircase structure. The conductive pillar has an upper conductive pillar end and a lower conductive pillar end opposing to the upper conductive pillar end. The contact pillar is electrically connected on one conductive stair layer of the conductive stair layers. The contact pillar has an upper contact end and a lower contact end opposing to the upper contact end. The upper contact end and the lower contact end are respectively electrically connected to the upper conductive pillar end of the conductive pillar and the one conductive stair layer.

### BACKGROUND

### Technical Field

The disclosure relates to a semiconductor structure and a method for manufacturing the same.

### Description of the Related Art

With development of the semiconductor technology, semiconductor devices have become smaller in size. In the semiconductor technology, shrinking of feature sizes, and improving operation speed, efficiency, density, and cost per Integrated circuit are important objectives. For satisfy customer need and the market demand, it is important to shrink devices in size and also to maintain the electricity of devices.

### SUMMARY

The present disclosure relates to a semiconductor structure and a method for manufacturing the same.

According to an embodiment, a semiconductor structure is provided. The semiconductor structure comprises a first staircase structure, a second staircase structure, a conductive pillar, and a contact pillar. The first staircase structure comprises conductive stair layers. The conductive pillar passes through the second staircase structure. The conductive pillar has an upper conductive pillar end and a lower conductive pillar end opposing to the upper conductive pillar end. The contact pillar is electrically connected on one conductive stair layer of the conductive stair layers. The contact pillar has an upper contact end and a lower contact end opposing to the upper contact end. The upper contact end and the lower contact end are respectively electrically connected to the upper conductive pillar end of the conductive pillar and the one conductive stair layer.

According to another embodiment, a semiconductor structure is provided. The semiconductor structure comprises a first staircase structure, a contact pillar, a semiconductor device, a conductive pillar, and a conductive element. The first staircase structure comprises stair layers each comprising a conductive stair layer. The contact pillar is electrically connected on one conductive stair layer of the conductive stair layers. The semiconductor device comprises an active device and/or a passive device. The semiconductor device is below the first staircase structure. The conductive element is over the first staircase structure and extended across coplanar first sidewall surfaces of the stair layers along a lateral direction. The conductive element is electrically connected between the conductive pillar and the contact pillar. The conductive pillar is electrically connected between the semiconductor device and the conductive element.

According to yet another embodiment, a method for manufacturing a semiconductor structure is provided. The method comprises the following steps. An insulating stacked structure is formed. The insulating stacked structure comprises first insulating layers and second insulating layers stacked alternately. The first insulating layers have a material different from a material of the second insulating layers. The insulating stacked structure comprises a staircase region and a bulk region adjacent to the staircase region. The second insulating layers of a portion of the staircase region and the bulk region are removed to form slits between the first insulating layers, while the second insulating layers of another portion of the staircase region are remained. The slits are filled with a conductive material.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1A illustrates a stereoscopic schematic diagram of a semiconductor structure according to an embodiment.

FIG. 1B illustrates a lateral cross-section view of the semiconductor structure.

FIG. 1C illustrates a top view of a semiconductor device and a conductive assembly.

FIG. 2 illustrates a lateral cross-section view of a memory material layer, a conductive layer and a pillar element according to another embodiment.

FIG. 3 illustrates a stereoscopic schematic diagram of a memory material layer, a conductive layer and a pillar element of a stacked bulk structure according to another embodiment.

FIG. 4 to FIG. 11 illustrate a method for manufacturing the semiconductor structure according to an embodiment.

### DETAILED DESCRIPTION

The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

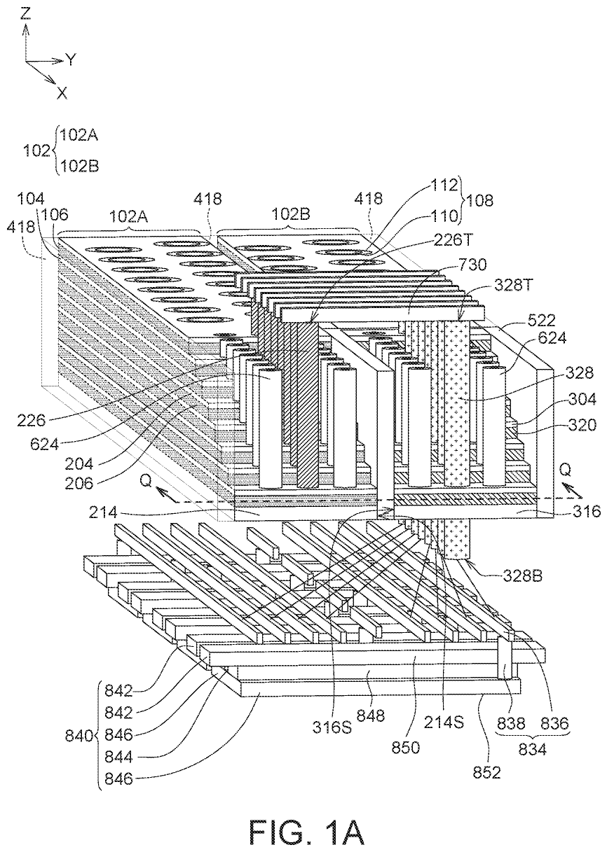

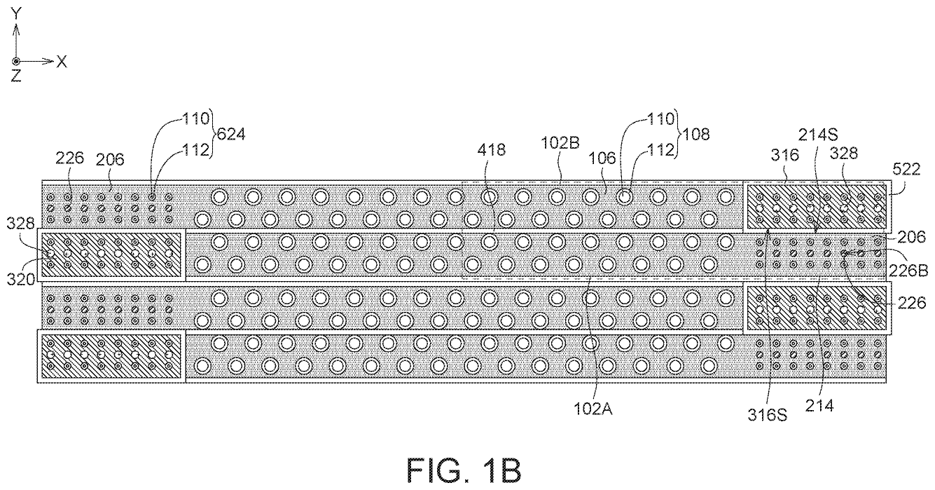

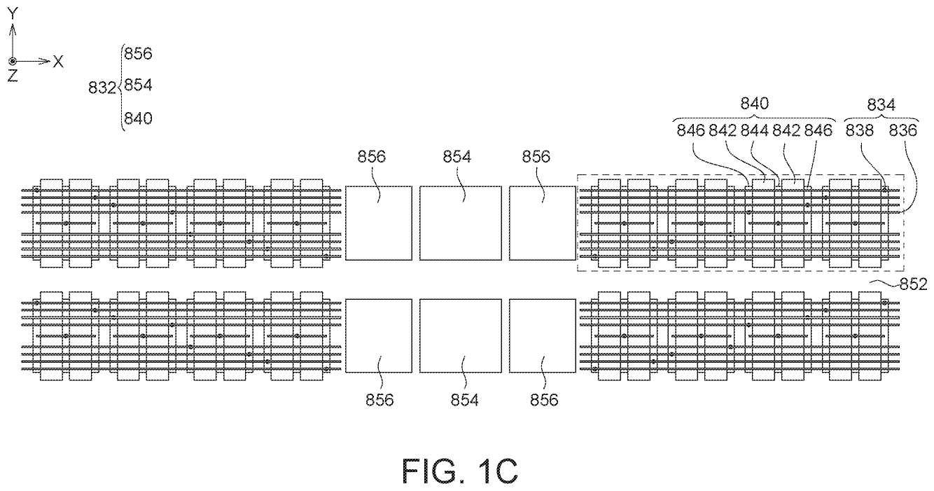

FIG. 1A is referred to, which illustrates a stereoscopic schematic diagram of a semiconductor structure according to an embodiment. A stacked bulk structure 102 may comprise insulating layers 104 and conductive layers 106 stacked alternately. The conductive layers 106 are separated from each other by the insulating layers 104. The memory device may be a 3D memory array having memory cells in the stacked bulk structure 102. Pillar elements 108 pass through the stacked bulk structure 102. In an embodiment, the pillar elements 108 comprise a channel element 110, and may be referred to as active pillar elements. The channel element 110 passes through the stacked bulk structure 102. The memory cells are defined in a memory material layer 112 between the channel element 110 and the conductive layers 106. The conductive layers 106 of the stacked bulk structure 102 may be functioned as word lines (WL). In an embodiment, the pillar element 108 may comprise the memory material layer 112 surrounding on a sidewall surface of the channel element 110. For example, the memory device may comprise a flash memory such a NOR flash memory, a NAND flash memory, etc., or other kinds of memory devices.

A first staircase structure 214, a second staircase structure 316 and the stacked bulk structure 102 may be non-overlapping with each other in a longitudinal direction (such as a vertical direction or a Z direction). The first staircase structure 214 and the second staircase structure 316 may be on the same side of the stacked bulk structure 102, and arranged along a Y direction. For example, the first staircase structure 214 and the second staircase structure 316 are on the same side of a stacked bulk structure 102A and a stacked bulk structure 102B respectively. An insulating strip 418 may be extended between side all surfaces of stacked bulk structure 102A and the stacked bulk structure 102B along an X direction for example. The conductive layers 106 of stacked bulk structure 102A are separated from the conductive layers 106 of the stacked bulk structure 102E by the insulating strip 418. In FIG. 1A, the insulating strip 418 is shown with a perspective view. Each of the first staircase structure 214 and the second staircase structure 316 comprises stair layers. A lower stair layer of the stair layers has an area larger than an area of an upper stair layer of the stair layers.

Each of the stair layers of the first staircase structure 214 comprises a conductive stair layer 206 and a first insulating stair layer 204. The conductive stair layers 206 and the first insulating stair layers 204 are stacked alternately. In an embodiment, the conductive stair layer 206 of one stair layer is under the first insulating stair layer 204 of the one stair layer. In another embodiment, the conductive stair layer 206 of one stair layer may be on the first insulating stair layer 204 of the one stair layer. The conductive stair layer 206 of the first staircase structure 214 may be continuously connected with the conductive layer 106 of the stacked bulk structure 102. The first insulating stair layer 204 of the first staircase structure 214 may be continuously connected with the insulating layer 104 of the stacked bulk structure 102.

The second staircase structure 316 may be an insulator. The stair layer of the second staircase structure 316 may comprise an insulating layer, and may be referred to as an insulating stair layer. In an embodiment, each of the stair layers of the second staircase structure 316 may comprise a first insulating stair layer 304 and a second insulating stair layer 320. The first insulating stair layers 304 and the second insulating stair layers 320 may be stacked alternately. In an embodiment, the second insulating stair layer 320 of one stair layer is under the first insulating stair layer 304 of the one stair layer. In another embodiment, the second insulating stair layer 320 of one stair layer may be on the first insulating stair layer 304 of the one stair layer. The first insulating stair layer 304 has a material different from a material of the second insulating stair layer 320. In embodiments, the second insulating stair layer 320, the conductive stair layer 206 of the first staircase structure 214, and the conductive layer 106 of the stacked bulk structure 102 are in the same level layer. The conductive stair layers 206 of the first staircase structure 214 are electrically insulated from the second staircase structure 316. An insulating wall element 522 surrounds on a sidewall surface of the second staircase structure 316.

Pillar elements 624 may be on the first staircase structure 214 and the second staircase structure 316. The pillar element 624 may also pass through the first staircase structure 214 or the second staircase structure 316 to the most bottom stair layer along the longitudinal direction. The pillar element 624 may have a material set identical with a material set of the pillar element 108. In an embodiment, the pillar element 624 may comprise a channel element and a memory material layer surrounding on a sidewall surface of the channel element. In embodiments, the pillar elements 624 may be dummy pillar elements. The pillar element 624 may be electrically floating. The present disclosure is not limited thereto. The pillar element 624 may have a material set different from a material set of the pillar element 108. The pillar element 624 may use any insulating material.

FIG. 1A and FIG. 1B are referred to. FIG. 1B illustrates a lateral cross-section view of the semiconductor structure along an extending line from a QQ line in FIG. 1A, The structure shown in FIG. 1A may correspond to a structure in a region extending vertically from a dashed rectangle shown in FIG. 1B. Contact pillars 226 are extended vertically on the conductive stair layers 206 of the first staircase structure 214. The contact pillar 226 is electrically connected to the conductive stair layer 206. The contact pillar 226 has an upper contact end 226T and a lower contact end 226B opposing to the upper contact end 226T. The lower contact end 226B of the contact pillar 226 is electrically and physically contact with the conductive stair layer 206. One contact pillar 226 electrically connected to an upper conductive stair layer 206 has a longitudinal size smaller than a longitudinal size of another contact pillar 226 electrically connected to a lower conductive stair layer 206. The conductive stair layer 206 of the first staircase structure 214 is electrically connected between the memory cell in the stacked bulk structure 102 and the contact pillar 226. Conductive pillars 328 pass through the second staircase structure 316. The conductive pillars 328 respectively pass through different stair layer amounts of the second staircase structure 316. A stair layer amount that one conductive pillar 328 close to the stacked bulk structure 102 passes through is more than a stair layer amount that another conductive pillar 328 far away from the stacked bulk structure 102 passes through. The conductive pillar 328 has an upper conductive pillar end 328T and a lower conductive pillar end 328B opposing to the upper conductive pillar end 328T, The lower conductive pillar end 328B may be below a bottom surface of the second staircase structure 316. The conductive pillars 328 passing through the second staircase structure 316 may have the same longitudinal size (such as a vertical distance between the upper conductive pillar end 328T and the lower conductive pillar end 328B).

The stair layers of the first staircase structure 214 have coplanar first sidewall surfaces 214S. The stair layers of the second staircase structure 316 have coplanar second sidewall surfaces 316S. The second sidewall surface 316S of the second staircase structure 316 faces towards the first sidewall surface 214S of the first staircase structure 214. In embodiments, a conductive element 730 is above the first staircase structure 214 and the second staircase structure 316, and is extended across the first sidewall surface 214S and the second sidewall surface 316S in a lateral direction perpendicular to the vertical direction. The conductive element 730 is electrically connected between the upper conductive pillar end 328T of the conductive pillar 328 and the upper contact end 226T of the contact pillar 226.

FIG. 1A and FIG. 1C are referred to. FIG. 1C illustrates a top view of a semiconductor device 832 and a conductive assembly 834 below or under the stacked bulk structure 102, the first staircase structure 214, and the second staircase structure 316. The conductive pillar 328 may be electrically connected to the semiconductor device 832 from the lower conductive pillar end 328B of the conductive pillar 328 through the conductive assembly 834 (for example comprising a first metal layer (M1) 836 or a conductive via 838, and so on) below or under the conductive pillar 328. The semiconductor device 832 may be overlapped with the first staircase structure 214, the second staircase structure 316 and/or the stacked bulk structure 102 in the vertical direction. The semiconductor device 832 comprises an active device and/or a passive device. For example, the active device may comprise a transistor 840, a diode, etc. The transistor 840 comprises a gate structure 842, a source/drain 844 and a source/drain 846. One of the source/drain 844 and the source/drain 846 is a source electrode, and the other of the source/drain 844 and the source/drain 846 is a drain electrode. The gate structure 842 comprises a gate dielectric layer 848 and a gate electrode 850. The gate dielectric layer 848 is on a substrate 852. The gate electrode 850 is on the gate dielectric layer 848. The source/drain 844 and the source/drain 846 are in the substrate 852 on opposing sides of the gate structure 842. The substrate 852 may comprise a semiconductor substrate, such as a silicon substrate or a silicon-on-insulator, or other suitable semiconductor materials. The transistor 840 may comprise a NMOS, a PMOS, a CMOS, a BJT, etc. The passive device may comprise a resistor, a capacitor and/or an inductor. For example, the lower conductive pillar end 328B of the conductive pillar 328 may be electrically connected to the source/drain 846 (such as the drain electrode) of the transistor 840. The semiconductor device 832 may comprise a CMOS invertor. The semiconductor device 832 and the conductive assembly 834 shown in FIG. 1A may correspond to a portion indicated with a dashed rectangle in FIG. 1C.

In an embodiment, a control circuit 854 of the semiconductor device 832 processes row address signals to select or de-select blocks or word lines. A signal of the control circuit 854 may be provided to a level shifter 856 to widen the voltage range, for example from a narrow input voltage range adapted for address signals, to a wider output range adapted for passing word line voltages that can be large magnitude positive voltages or larger magnitude negative voltages. Blocks or word lines are selected or de-selected by applying appropriate signals from the level shifter 856 to the local driver (such as the (pass) transistors 840) that pass or block word line voltages from reaching word lines in the memory array. The memory array stores data, and may be a volatile or non-volatile memory.

In embodiments, a circuit routing comprises the conductive element 730 extended across the first sidewall surface 214S of the first staircase structure 214 and the second sidewall surface 316S of the second staircase structure 316, and comprises the conductive pillar 328 passing through the second staircase structure 316. This circuit routing does not occupy an area outside the first staircase structure 214 and the second staircase structure 316 (i.e. a region on a side of the first staircase structure 214 and the second staircase structure 316 opposing to the stacked bulk structure 102). Therefore, an occupied area for a unit device can be reduced, and device density disposed on a chip can be increased. In addition, this circuit routing can also provide a short signal path (such as a current path). The conductive pillar 328 passing through the second staircase structure 316 is close to the semiconductor device 832 and the conductive assembly 834 below or under the first staircase structure 214, the second staircase structure 316 and the stacked bulk structure 102, and therefore can result in a short signal path. As such, operating efficiency of the device can be improved.

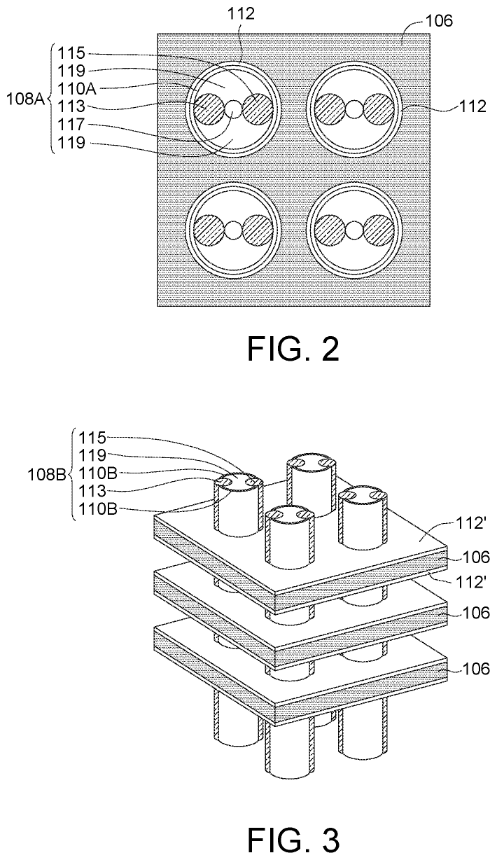

FIG. 2 illustrates a lateral cross-section view of the memory material layer 112, the conductive layer 106 and a pillar element 108A according to another embodiment. The difference between the pillar element 108A and the pillar element 108 shown in FIG. 1A and FIG. 1B is disclosed with the following description. The pillar element 108A comprises a channel element 110A, a source/drain pillar 113, a source/drain pillar 115, an insulating pillar 117 and a dielectric material layer 119. The insulating pillar 117 is between the source/drain pillar 113 and the source/drain pillar 115. The source/drain pillar 113 and source/drain pillar 115 are separated from each other by the insulating pillar 117. One of the source/drain pillar 113 and the source/drain pillar 115 is a source, and the other of the source/drain pillar 113 and the source/drain pillar 115 is a drain. The dielectric material layer 119 is between the channel element 110A and the source/drain pillar 113, the source/drain pillar 115 and the insulating pillar 117. The channel element 110A shown in FIG. 2 is different from the channel element 110 shown in FIG. 1A and FIG. 1B in that the channel element 110A has a closed ring shape. The channel element 110A surrounds the outside of the source/drain pillar 113, the source/drain pillar 115, the insulating pillar 117 and the dielectric erial layer 119.

FIG. 3 illustrates a stereoscopic schematic diagram of a memory material layer 112′, the conductive layer 106 and a pillar element 108B of a stacked bulk structure 102′ according to another embodiment. The difference between the pillar element 108B and the pillar element 108A shown in FIG. 2 is disclosed with the following description. The pillar element 108B comprises a channel element 110B, the source/drain pillar 113, the source/drain pillar 115 and the dielectric material layer 119. The source/drain pillar 113 and the source/drain pillar 115 are separated from each other by the dielectric material layer 119. The channel element 110B shown in FIG. 3 is different from the channel element 110A shown in FIG. 2 in that the channel element 110B has an open ring shape, and has opposing ends respectively electrically connected to the source/drain pillar 113 and the source/drain pillar 115. The memory material layer 112′ is different from the memory material layer 112 illustrated with referring to FIG. 1A and FIG. 1B in that the memory material layer 112′ is on upper and lower surfaces of the conductive layers 106, and may be extended between an outer side all surface of the pillar element 108B and the conductive layer 106.

In an embodiment, in a stereoscopic schematic diagram of a stacked bulk structure, the memory material layer 112 illustrated with referring to FIG. 2 may be arranged on the upper and lower surfaces of the conductive layer 106, and may be extended between an outer sidewall surface of the pillar element 108A and the conductive layer 106, similar to the arrangement for the memory material layer 112′ illustrated with referring to FIG. 3.

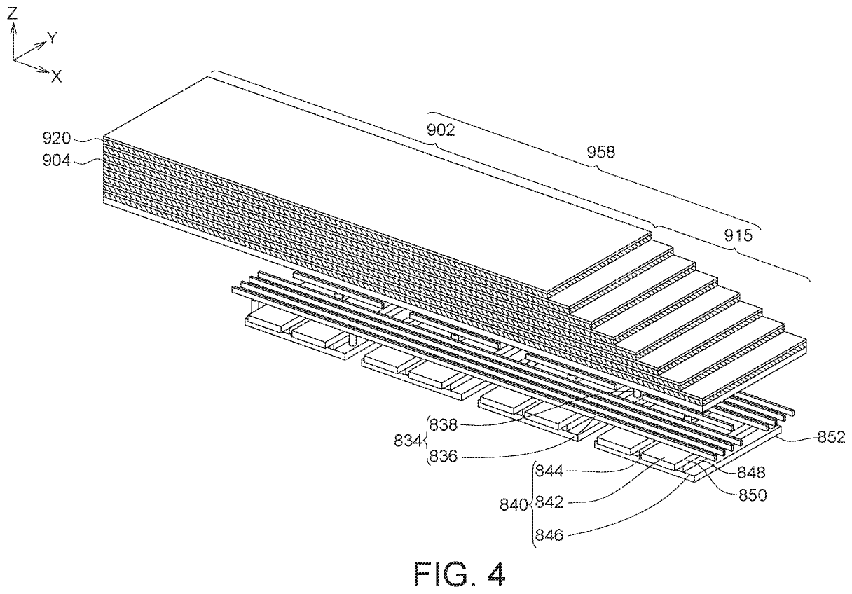

FIG. 4 to FIG. 11 illustrate a method for manufacturing the semiconductor structure according to an embodiment.

FIG. 4 is referred to. The substrate 852 is provided. The substrate 852 may comprise a semiconductor substrate. The semiconductor device is formed on the substrate 852. In an embodiment, the semiconductor device may comprise the transistor 840. The gate structure 842 of the transistor 840 is formed on the substrate 852. The gate structure 842 comprises the gate dielectric layer 848 and the gate electrode 850. The gate dielectric layer 848 is formed on the substrate 852. The gate electrode 850 is formed on the gate dielectric layer 848. For example, the gate electrode 850 may comprise polysilicon or other suitable conductive materials, such as single-crystal silicon, a metal (for a metal gate), a metal silicide and so on. The source/drain 844 and the source/drain 846 of the transistor 840 are formed in the substrate 852 on opposing sides of the gate structure 842. The source/drain 844 and the source/drain 846 may be formed by a doping process.

The conductive assembly 834 may be formed over the semiconductor device. For example, the conductive assembly 834 may comprise the conductive vias 838 electrically connected to and formed on the gate electrode 850, the source/drain 844 and the source/drain 846 of the transistor 840. The conductive assembly 834 may comprise a conductive layer such as the first metal layer (M1) 836 electrically connected to and formed on the conductive via 838. The conductive via 838 and the conductive layer may be formed in an inter-layer dielectric layer (not shown) or on the inter-layer dielectric layer. The present disclosure is not limited thereto. The conductive assembly 834 may comprise other possible conductive circuits formed in the inter-layer dielectric layer or on the inter-layer dielectric layer.

An insulating stacked structure 958 is formed over the semiconductor device (comprising the transistor 840), the conductive assembly 834 and the inter-layer dielectric layer (not shown). For example, the insulating stacked structure 958 may comprise first insulating layers 904 and second insulating layers 920 stacked alternately. In embodiments, the first insulating layers 904 have a material different from a material of the second insulating layers 920. For example, the first insulating layer 904 may comprise an oxide such as silicon oxide. The second insulating layer 920 may comprise a nitride such as silicon nitride. The present disclosure is not limited thereto. The first insulating layer 904 and the second insulating layer 920 may use other suitable insulating materials. A thickness of a staircase region 915 of the insulating stacked structure 958 may be thinned by using a photolithography etching method from a top surface of the staircase region 915 adjacent to a bulk region 902 of the insulating stacked structure 958. In an embodiment, an insulating film (for example comprising an oxide such as silicon oxide etc., not shown) may be formed on the bulk region 902 and the staircase region 915 of the insulating stacked structure 958. For example, the insulating film (not shown) on the insulating stacked structure 958 may be flattened by a CMP step.

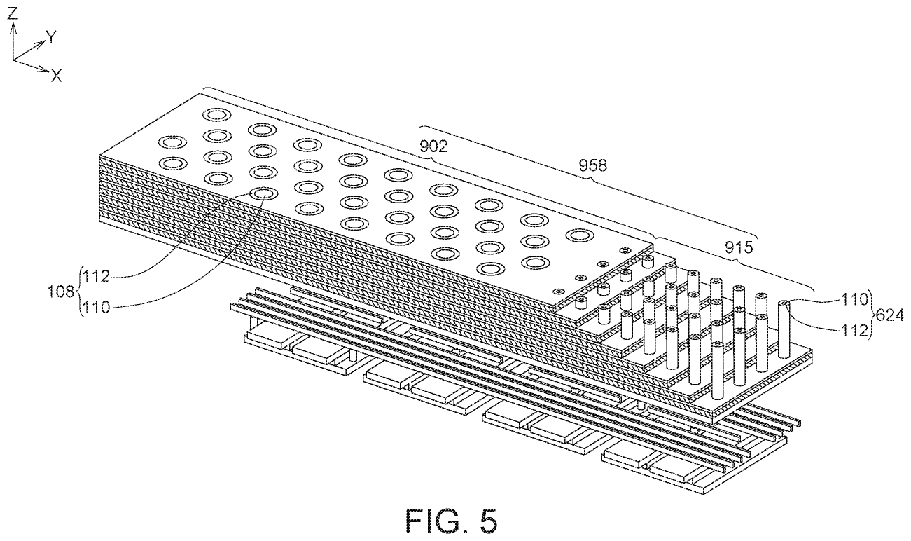

FIG. 5 is referred to. The pillar element 108 and the pillar element 624 respectively passing through the bulk region 902 and the staircase region 915 of the insulating stacked structure 958 are formed. The pillar element 108 and the pillar element 624 may also pass through the insulating film (not shown) on the insulating stacked structure 958. In an embodiment, the pillar element 108 and the pillar element 624 may be formed by a method comprising forming an opening in the insulating stacked structure 958 and the insulating film (not shown) by a photolithography etching step, and then filling the opening with a proper pillar material. In an embodiment, the pillar element 108 and the pillar element 624 may be formed simultaneously, and may comprise the channel element 110 and the memory material layer 112. The memory material layer 112 is formed on a sidewall surface of the opening. The memory material layer 112 may comprise any kind of charge trapping structure, such as an ONO structure, an ONONO structure, an ONONONO structure, or BE-SONGS structure, etc. For example, a charge trapping layer may use a nitride such as silicon nitride, or other high-K materials comprising a metal oxide such as Al₂O₃, HfO₂, and the like. The channel element 110 is formed in the opening. In another embodiment, the pillar element 108 and the pillar element 624 may be formed individually with using different process steps. The pillar element 108 and the pillar element 624 may have different material sets.

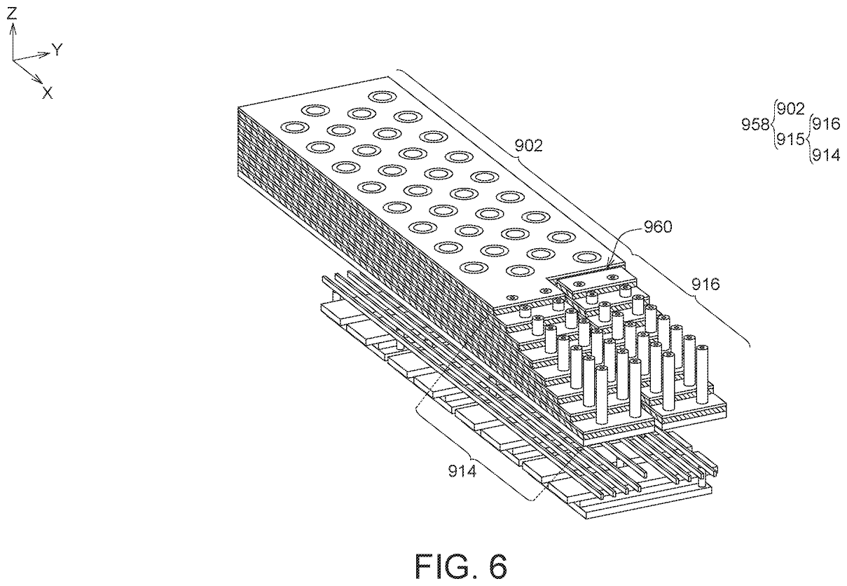

FIG. 6 is referred to. A recess 960 may be formed in the staircase region 915 of the insulating stacked structure 958 and the insulating film (not shown) on the staircase region 915 by using a photolithography etching step. The recess 960 divides the staircase region 915 of the insulating stacked structure 958 into a portion 914 and a portion 916. The portion 916 of the staircase region 915 is separated from the portion 914 of the staircase region 915 and the bulk region 902 by the recess 960. The recess 960 may have a closed rectangle ring shape. The portion 916 of the staircase region 915 of the insulating stacked structure 958 may be the second staircase structure 316 illustrated with referring to FIG. 1A.

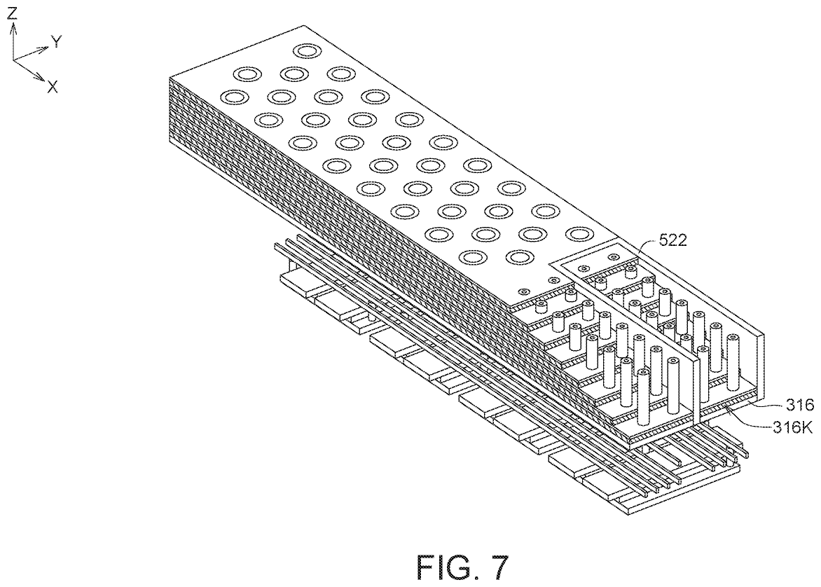

FIG. 7 is referred to. The recess 960 may be filled with an insulating material to form the insulating wall element 522. The insulating wall element 522 may surround on the sidewall surface of the second staircase structure 316, including a sidewall surface 316K indicated in FIG. 7. In an embodiment, the insulating wall element 522 may comprise an oxide such as silicon oxide.

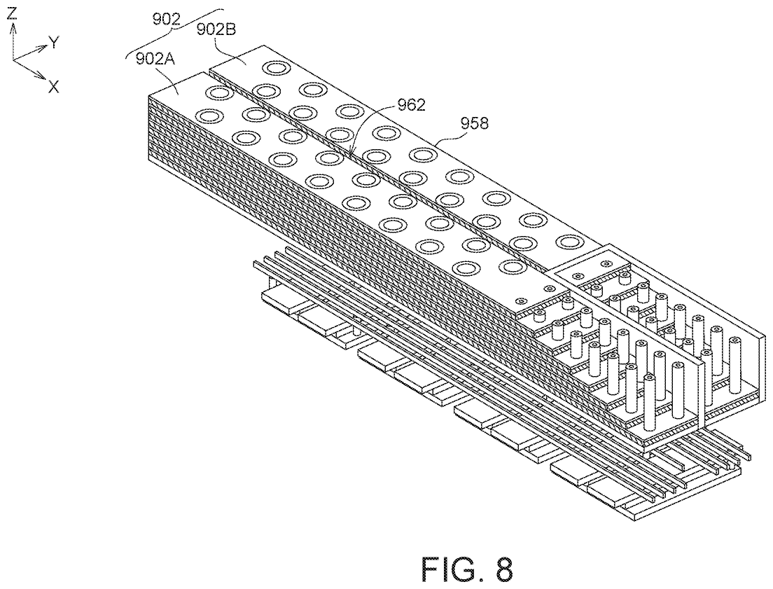

FIG. 8 is referred to. A trench 962 may be formed in the insulating stacked structure 958 by using a photolithography etching step. The bulk region 902 of the insulating stacked structure 958 may be divided into a portion 902A and a portion 902B by the trench 962.

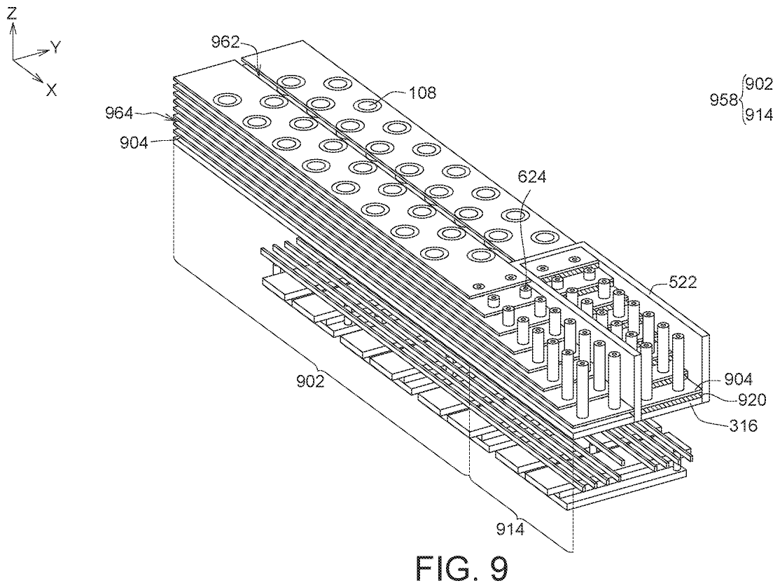

FIG. 9 is referred to. The second insulating layer 920 (comprising a nitride such as silicon nitride) of the portion 914 of the staircase region and the bulk region 902 of the insulating stacked structure 958 exposed by the trench 962 may be removed with using a selective etching step so as to form slits 964 between the first insulating layers 904 (comprising an oxide such as silicon oxide). The insulating wall element 522 (comprising an oxide such as silicon oxide) and the insulating film (comprising an oxide such as silicon oxide, not shown) on the second staircase structure 316 are not etched by this etching step substantially. The insulating wall element 522 can be functioned as a protection element preventing the second insulating layers 920 of the second staircase structure 316 from being etched. Therefore, the second insulating layers 920 of the second staircase structure 316 can be remained from the etching step. The insulating film (not shown) on the second staircase structure 316 also can provide a protection effect avoiding the etching. In an embodiment, the etch step may comprise a wet etch method, for example using a hot phosphoric acid, or other suitable etch methods. In embodiments, the first insulating layer 904, the second insulating layer 920, the insulating wall element 522 and the insulating film on the second staircase structure 316 may use other suitable materials based on the selective etching principle described herein. The slit 964 exposes sidewall surfaces of the pillar element 108 and the pillar element 624, and a sidewall surface of the insulating wall element 522. The pillar elements 108 and the pillar elements 624 exposed by the slits 964 can support and steady the first insulating layers 904 exposed by the slits 964.

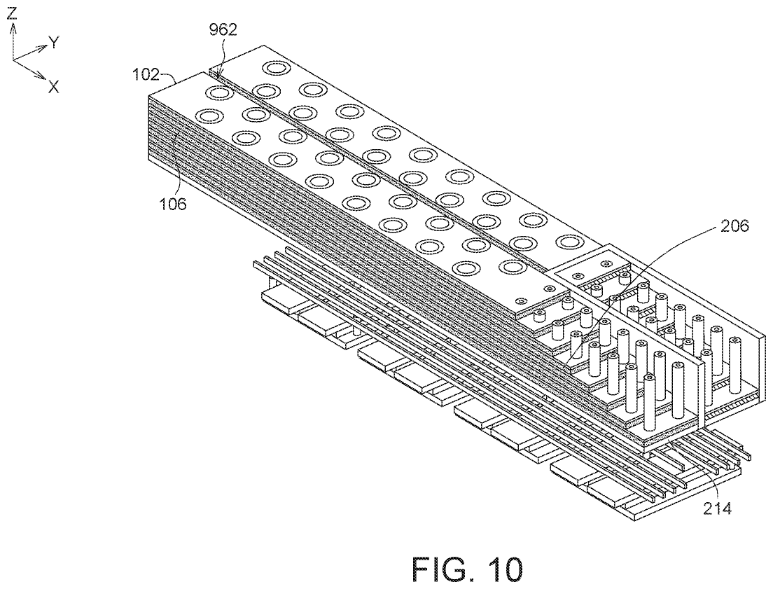

FIG. 10 is referred to. The slits 964 are filled with a conductive material. The conductive material formed in the bulk region 902 forms the conductive layers 106. The conductive material formed in the portion 914 of the staircase region 915 forms the conductive stair layers 206. As such, the stacked bulk structure 102 and the first staircase structure 214 are formed.

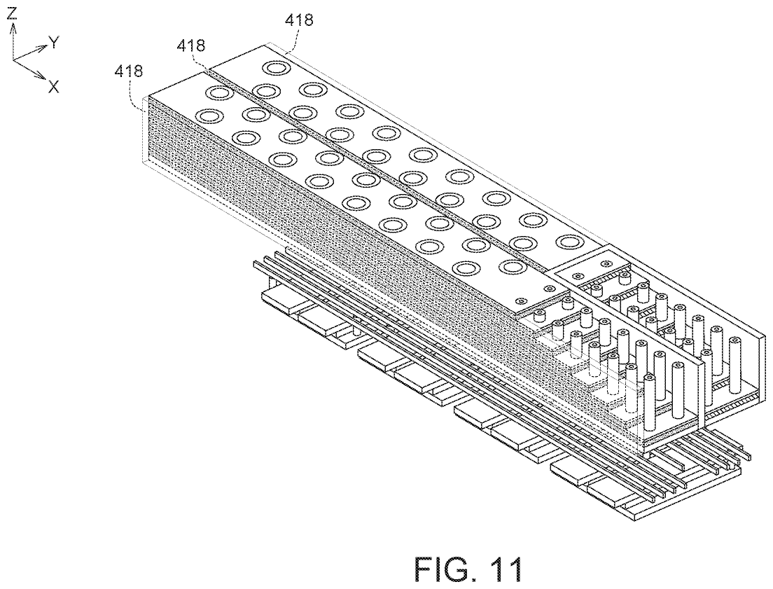

FIG. 11 is referred to. The trench 962 is filled with an insulating material to form the insulating strip 418.

FIG. 1A is referred to. The contact pillars 226 are formed to land on the conductive stair layers 206. The contact pillar 226 may pass through the insulating film (not shown) on the first staircase structure 214, and the first insulating stair layer 204 on the conductive stair layer 206 on which the contact pillar 226 landing. The conductive pillars 328 are formed to pass through the second staircase structure 316. The conductive pillars 328 may also pass through the insulating film (not shown) on the second staircase structure 316. The contact pillar 226 and the conductive pillar 328 may be formed by a method comprising forming a hole by using a photolithography etching process, and then filling the hole with a conductive material. Then, the conductive element 730 may be formed on the contact pillar 226 and the conductive pillar 328.

In an embodiment, the pillar element 108 formed in the process step illustrated with referring to FIG. 5 may be replaced by the pillar element 108A illustrated with referring to FIG. 2 so as to form the semiconductor structure shown in FIG. 2.

In an embodiment, the step for forming the memory material layer 112 illustrated with referring to FIG. 5 may be omitted. After the process step illustrated with referring to FIG. 9, the memory material layer 112 is formed in the slits 964. Then process steps similar to the process steps according to the illustration from FIG. 10 to FIG. 1A may be performed. By which, the semiconductor structure illustrated with referring to FIG. 2 may be formed.

In another embodiment, the pillar element 108 formed in the process step illustrated with referring to FIG. 5 may be replaced by the pillar element 108B illustrated with referring to FIG. 3. In addition, the step for forming the memory material layer 112 illustrated with referring to FIG. 5 may be omitted. After the process step illustrated with referring to FIG. 9, the memory material layer 112′ is formed in the slits 964. Then process steps similar to the process steps according to the illustration from FIG. 10 to FIG. 1A may be performed. By which, the semiconductor structure illustrated with referring to FIG. 3 may be formed.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a first staircase structure comprising conductive stair layers;
a second staircase structure;
a conductive pillar passing through the second staircase structure and having an upper conductive pillar end and a lower conductive pillar end opposing to the upper conductive pillar end; and
a contact pillar electrically connected on one conductive stair layer of the conductive stair layers, and having an upper contact end and a lower contact end opposing to the upper contact end; wherein the upper contact end and the lower contact end are respectively electrically connected to the upper conductive pillar end of the conductive pillar and the one conductive stair layer.

2. The semiconductor structure according to claim 1, further comprising a semiconductor device comprising an active device and/or a passive device, and being below the first staircase structure and the second staircase structure, the lower conductive pillar end of the conductive pillar is electrically connected to the semiconductor device.

3. The semiconductor structure according to claim 1, further comprising a stacked bulk structure, another stacked bulk structure and an insulating strip, wherein the semiconductor structure comprising a plurality of the contact pillars on the conductive stair layers, the insulating strip is extended between sidewall surfaces of the stacked bulk structure and the another stacked bulk structure, wherein the semiconductor structure comprises memory cells in the stacked bulk structure and the another stacked bulk structure, the first staircase structure is electrically connected between the memory cells in the stacked bulk structure and the plurality of the contact pillars.

4. The semiconductor structure according to claim 1, further comprising dummy pillar elements on the first staircase structure and/or the second staircase structure.

5. The semiconductor structure according to claim 1, comprising a plurality of the contact pillars on the conductive stair layers, wherein the semiconductor structure further comprises a stacked bulk structure, a pillar element and a memory material layer,
the stacked bulk structure comprises insulating layers and conductive layers separated from each other by the insulating layers,
the pillar element passes through the stacked bulk structure, and comprises a channel element, wherein memory cells are defined in the memory material layer between the channel element and the conductive layers, the first staircase structure is electrically connected between the memory cells and the plurality of the contact pillars.

6. The semiconductor structure according to claim 5, further comprising dummy pillar elements on the first staircase structure and/or the second staircase structure, wherein the dummy pillar elements have a material set identical with a material set of the pillar element.

7. The semiconductor structure according to claim 1, further comprising an insulating wall element surrounding a sidewall surface of the second staircase structure.

8. The semiconductor structure according to claim 1, further comprising another conductive pillar and another contact pillar, wherein
a stair layer amount of the second staircase structure that the conductive pillar passes through is more than a stair layer amount of the second staircase structure that the another conductive pillar passes through, a longitudinal size of the conductive pillar is identical with a longitudinal size of the another conductive pillar.
the another contact pillar is electrically connected on another conductive stair layer of the conductive stair layers, the another conductive stair layer is above the one conductive stair layer, the another contact pillar has a longitudinal size smaller than a longitudinal size of the contact pillar.

9. The semiconductor structure according to claim 1, further comprising a conductive element, wherein each of the first staircase structure and the second staircase structure comprises stair layers, the stair layers of the first staircase structure have coplanar first sidewall surfaces, the stair layers of the second staircase structure have coplanar second sidewall surfaces, the conductive element is extended across the first sidewall surfaces and the second sidewall surfaces, and is electrically connected between the conductive pillar and the contact pillar.

10. The semiconductor structure according to claim 1, wherein each of the first staircase structure and the second staircase structure comprises stair layers, an area of a lower stair layer of the stair layers is larger than an area of an upper stair layer of the stair layers.

11. The semiconductor structure according to claim 1, wherein each of the first staircase structure and the second staircase structure comprises stair layers, each of the stair layers comprises a first insulating stair layer, each of the stair layers of the second staircase structure further comprises a second insulating stair layer on a side of the first insulating stair layer, a material of the first insulating stair layers is different from a material of the second insulating stair layers, the stair layers of the first staircase structure comprise the conductive stair layers on a side of the first insulating stair layers.

12. The semiconductor structure according to claim 1, wherein each of the first staircase structure and the second staircase structure comprises stair layers, the stair layers of the first staircase structure have coplanar first sidewall surfaces, the stair layers of the second staircase structure have coplanar second sidewall surfaces facing towards the first sidewall surfaces.

13. The semiconductor structure according to claim 1, wherein the first staircase structure is electrically insulated from the second staircase structure.

14. The semiconductor structure according to claim 13; wherein the second staircase structure comprises insulating stair layers; the insulating stair layers and the conductive stair layers of the first staircase structure are in the same level layers.

15. The semiconductor structure according to claim 1, further comprising a stacked bulk structure, wherein the semiconductor structure comprises memory cells in the stacked bulk structure, the first staircase structure and the second staircase structure are on the same side of the stacked bulk structure.

16. A semiconductor structure; comprising:
a first staircase structure comprising stair layers each comprising a conductive stair layer;
a contact pillar electrically connected on one conductive stair layer of the conductive stair layers
a semiconductor device comprising an active device and/or a passive device, and below the first staircase structure;
a conductive pillar; and
a conductive element over the first staircase structure and extended across coplanar first sidewall surfaces of the stair layers along a lateral direction, wherein the conductive element is electrically connected between the conductive pillar and the contact pillar, the conductive pillar is electrically connected between the semiconductor device and the conductive element.

17. The semiconductor structure according to claim 16, further comprising a memory device, wherein the semiconductor device comprises a transistor, wherein the contact pillar, the conductive pillar and the conductive element are electrically connected between the memory device and a source/drain of the transistor.

18. A method for manufacturing a semiconductor structure, comprising:
forming an insulating stacked structure, wherein the insulating stacked structure comprises first insulating layers and second insulating layers stacked alternately, the first insulating layers have a material different from a material of the second insulating layers, the insulating stacked structure comprises a staircase region and a bulk region adjacent to the staircase region;
removing the second insulating layers of a portion of the staircase region and the bulk region to form slits between the first insulating layers, while remaining the second insulating layers of another portion of the staircase region; and
filling the slits with a conductive material.

19. The method for manufacturing the semiconductor structure according to claim 18, further comprising:
forming a semiconductor device on a substrate, wherein the insulating stacked structure is formed over the semiconductor device.

20. The method for manufacturing the semiconductor structure according to claim 18, wherein the conductive material formed in the portion of the staircase region forms conductive stair layers; the method further comprises:
before the removing the second insulating layers of the portion of the staircase region and the bulk region, forming pillar elements passing through the bulk region and the staircase region of the insulating stacked structure respectively, wherein slits expose sidewall surfaces of the pillar elements; the pillar elements comprise a channel element;
after the filling the slits with the conductive material; forming contact pillar landing on the conductive stair layers; and
after the filling the slits with the conductive material, forming conductive pillars passing through the another portion of the staircase region of the insulating stacked structure.
